(19) United States
(12) Patent Application Publication
(10) Pub. No.: US 2005/0230850 A1
(43) Pub. Date: Oct. 20, 2005

(54) Microelectronic assembly having a redistribution conductor over a microelectronic die

(76) Inventors: Brian C. Taggart, Phoenix, AZ (US); Robert M. Nickerson, Chandler, AZ (US); Ronald L. Spreitzer, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/829,039

(22) Filed: Apr. 20, 2004

(51) Int. Cl. H01L 23/48

(52) U.S. Cl. 257/784

(57) ABSTRACT

A microelectronic assembly is provided, having redistribution conductors that are formed over a microelectronic die of the assembly instead of through a substrate to which the microelectronic die is mounted. A redistribution conductor is formed by a pair of contacts on the die and a conductive portion connecting the contacts to one another. A wirebonding wire is attached to each contact. One of the wirebonding wires may be used to connect to a terminal on the substrate, a terminal on another die, or to another contact on the same die.

### BACKGROUND OF THE INVENTION

1). Field of the Invention

This invention relates to a microelectronic assembly and the manner according to which contacts and terminals can be connected for purposes of redistributing current.

2). Discussion of Related Art

Integrated circuits are often manufactured in and on semiconductor wafers. A wafer is subsequently “singulated” or “diced” into individual dies. Each die is then mounted to a package substrate for purposes of structural integrity and providing signals, power, and ground to and from an integrated circuit in the die. Wirebonding wires may connect contacts on the die to terminals on the substrate. The terminals on the substrate are, in turn, connected through vias and other conductors to solder balls on an opposing side of the substrate.

It is often also required to connect one of the terminals to a solder ball on an opposing side of the die. In order to accomplish such redistribution of signals, conductors are formed out of metal layers in the substrate. More metal layers allow for more flexibility in design and more connections that can be made between components located on opposing sides of the die. A large number of metal layers in the substrate, however, increases the overall cost of the substrate. There is thus a trade-off between flexibility in the redistribution and the cost of the microelectronic assembly.

### BRIEF DESCRIPTION OF THE DRAWINGS

The invention is described by way of examples with reference to the accompanying drawings, wherein:

FIG. 1 is a plan view of a microelectronic assembly according to one embodiment of the invention;

FIG. 2 is a cross-sectional side view on 2-2 in FIG. 1;

FIG. 3 is a cross-sectional side view on 3-3 in FIG. 1;

FIG. 4 is a plan view of a microelectronic assembly according to another embodiment of the invention;

FIG. 5 is a cross-sectional side view on 5-5 in FIG. 4;

FIG. 6 is a plan view of a microelectronic assembly, according to a further embodiment of the invention; and

FIG. 7 is a cross-sectional view on 7-7 in FIG. 6.

### DETAILED DESCRIPTION OF THE INVENTION

A microelectronic assembly is provided, having redistribution conductors that are formed over a microelectronic die of the assembly instead of through a substrate to which the microelectronic die is mounted. A redistribution conductor is formed by a pair of contacts on the die and a conductive portion connecting the contacts to one another. A wirebonding wire is attached to each contact. One of the wirebonding wires may be used to connect to a terminal on the substrate, a terminal on another die, or to another contact on the same die.

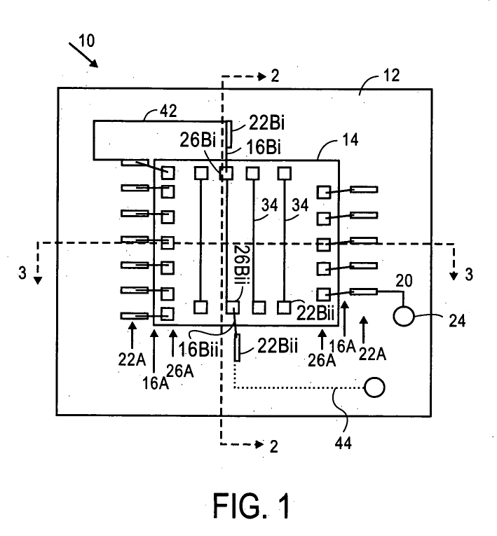

FIGS. 1, 2, and 3 illustrate a microelectronic assembly 10, according to one embodiment of the invention, including a package substrate subassembly 12, a die subassembly 14, and wirebonding wires 16.

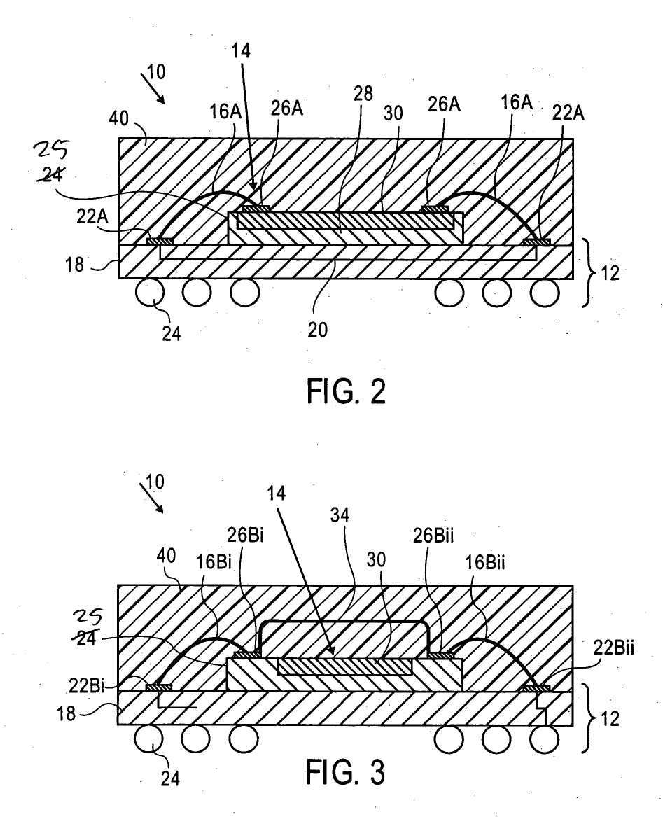

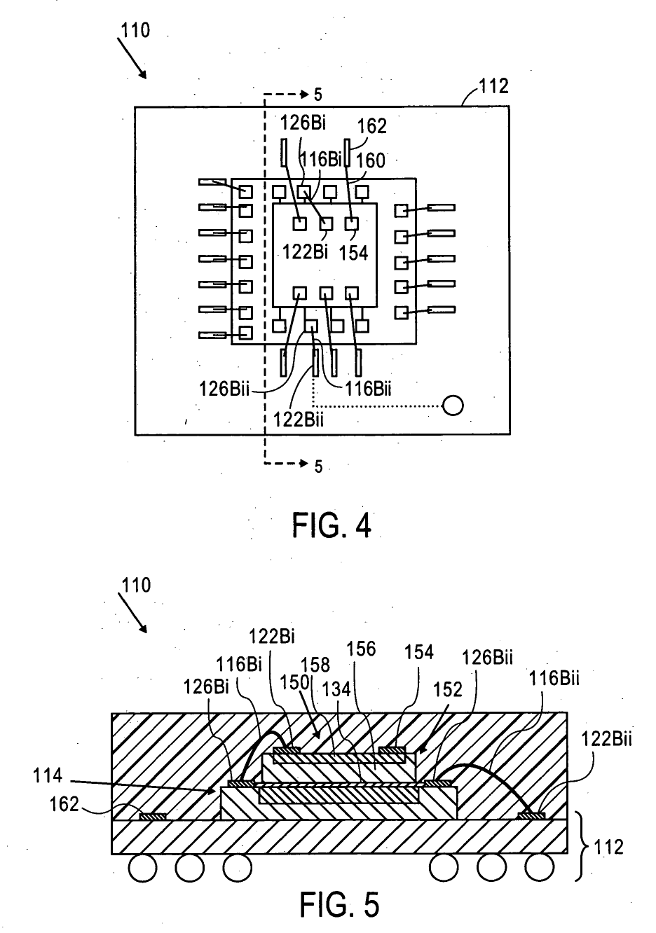

Referring specifically to FIG. 2, the package substrate subassembly 12 includes a package substrate 18, conductors 20 formed in the substrate 18, terminals 22 at an upper surface of the substrate 18, and solder ball contacts 24 on a lower surface of the substrate 18. The substrate 18 is multi-layer substrate with a plurality of alternating dielectric and metal layers. The conductors 20 are formed out of the metal layers and vias that are formed through the dielectric layers. In the example illustrated, two of the terminals 22A are connected to one another by one of the conductors 20.

Each one of the solder ball contacts 24 is also connected through a respective conductor 20 to one or more of the terminals 22A. The number of connections that can be made between the solder ball contacts 24 and the terminals 22A depends on the number of metal layers in the substrate 18; a larger number of metal layers allows for a larger number of connections. The number of metal layers in the substrate 18 should, however, be maintained as low as possible to reduce the cost of the substrate 18.

The die subassembly 14 includes a microelectronic die 25 and contacts 26 formed at an upper surface of the die 25. The die 25 includes a die substrate 28 and an integrated circuit 30 formed on the die substrate 28. The contacts 26 include functional contacts 26A that are connected to the integrated circuit 30. The integrated circuit 30 includes a multitude of transistors and other electronic components that are interconnected with one another. Signals, power, and ground can be provided through the functional contacts 26A to or from the electronic components of the integrated circuit 30.

The wirebonding wires 16 include functional wirebonding wires 16A. Each functional wirebonding wire 16A has one end portion attached to one of the functional terminals 22A, and an opposing end portion attached to one of the functional contacts 26A. The functional contacts 26A are connected through the respective functional wirebonding wires 16A and the respective functional contacts 26A to the integrated circuit 30.

Referring to FIG. 3, a re-routing conductor is formed by a pair of re-routing terminals 22Bi and 22Bii, a pair of re-routing wirebonding wires 16Bi and 16Bii, a pair of re-routing contact pads 26Bi and 26Bii, and an intermediate wirebonding wire 34. The re-routing terminals 22Bi and 22Bii are located on opposing sides and outside an area of the die subassembly 14. Each one of the re-routing contacts 26Bi and 26Bii is located near an edge of the die 25 and close to a respective one of the re-routing terminals 22Bi or 22bii, respectively. Both re-routing contacts 26Bi and 26Bii are disconnected from the integrated circuit 30. The re-routing contacts 26Bi and 26Bii are thus not in direct communication with the integrated circuit 30. Any communication from one of the re-routing contacts 26Bi or 26Bii is via one of the re-routing wirebonding wires 16Bi and re-routing terminals 22Bi. The intermediate wirebonding wire 34 has opposing ends connected to the respective re-routing contacts 26Bi and 26Bii. A central portion of the intermediate wirebonding wire 34 extends across the integrated circuit 30.

As illustrated in FIGS. 2 and 3, an encapsulant 40 is formed. The encapsulant 40 covers the die subassembly 14, exposed upper surfaces of the package substrate subassembly 12, and also the intermediate wirebonding wire 34.

Referring again to FIG. 1, the functional terminals 22A, functional contacts 26A, and functional wirebonding wires 16A are located along the left and right edges of the die subassembly 14. The re-routing terminals 26Bi and 26Bii are located along back and front edges of the die subassembly 14. A re-routing conductor trace 42 connects one of the functional terminals 22A along the left edge of the die subassembly 14, with one of the re-routing terminals 22Bi along the back edge of the die subassembly 14. A further conductor 44 connects one of the re-routing terminals 22Bii with one of the solder ball contacts 24. It can thus be seen that the functional terminal 22A in the top left is connected to the solder ball contact 24 in the bottom right, with a minimal amount of re-routing within the package substrate subassembly 12 and by using the re-routing conductor formed by the redistribution conductor formed by the re-routing terminal 22Bi, wirebonding wire 16Bi, re-routing contact 26Bi, intermediate wirebonding wire 34, re-routing contact 26Bii, wirebonding wire 16Bii, and re-routing terminal 22Bii.

Although only a single pair of re-routing terminals 22Bi and 22Bii is shown, it should be understood that there may be additional re-routing conductors that are similar to the re-routing conductor illustrated in FIG. 1. For this purpose, a plurality of intermediate wirebonding wires 34 are shown parallel to one another in FIG. 1. Each intermediate wirebonding wire 34 forms part of a separate re-routing conductor from the back edge to the front edge of the die subassembly 14.

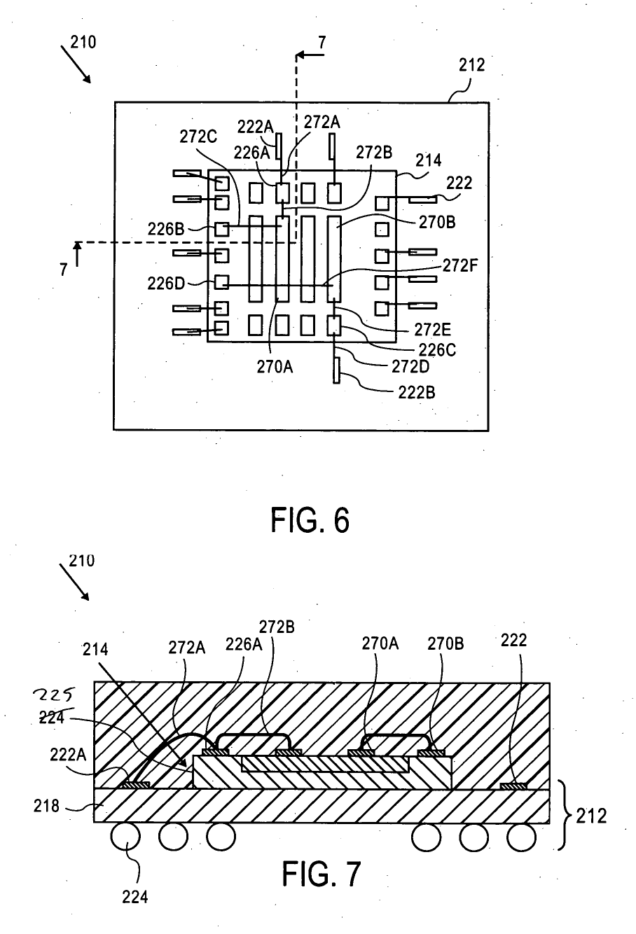

FIGS. 5 and 6 illustrate a microelectronic assembly 110 according to another embodiment of the invention, including a package substrate subassembly 112, a first die subassembly 114, and a second die subassembly 150. The microelectronic assembly 110 further has a re-routing conductor formed by a first redistribution terminal 122Bi, a first redistribution wirebonding wire 116Bi, a pair of redistribution contacts 126Bi and 126 Bii, a redistribution conductor trace 134, a second redistribution wirebonding wire 116Bii, and a second redistribution terminal 122Bii.

The package substrate subassembly 112 and the first die subassembly 114 are similar to the package substrate subassembly 12 and die subassembly 14 of FIG. 1. In this respect, the similarities between FIGS. 3 and 5 should be evident.

The first redistribution wirebonding wire 116Bi has opposing ends that are attached respectively to the first redistribution terminal 122Bi and to the first redistribution contact 126Bi. The redistribution conductor trace 134 has opposing ends connected to the redistribution contacts 126Bi and 126Bii. The redistribution conductor trace 134 runs over the integrated circuit of the first die subassembly 114, without communicating therewith. The second die subassembly 150 is placed over the redistribution conductor trace 134, with the redistribution contacts 126Bi and 126Bii on opposing sides and outside an area of the second die subassembly 150.

The second die subassembly 150 is located on the first die subassembly 114. The second die subassembly 150 includes a microelectronic die 152 and a plurality of terminals 154 formed on the die 152. The die 152 includes a die substrate 156 and an integrated circuit 158 formed on the die substrate 156. The terminals 154 and the first redistribution terminal 122Bi are formed along edges of the second die subassembly 150, and are in direct communication with the integrated circuit 158.

The second redistribution wirebonding wire 116Bii has opposing ends connected respectively to the second redistribution contact 126Bii, and the second redistribution terminal 122Bii.

It can thus be seen that the first redistribution terminal 122Bi on the left of the second die subassembly 150 is connected to the second redistribution terminal 122Bii without the need for re-routing any signals through a substrate of the package substrate subassembly 112. Further functional wirebonding wires 160 can be used to connect terminals 162 of the package substrate subassembly 112 directly to terminals 154 of the second die subassembly 150.

FIGS. 6 and 7 illustrate a microelectronic assembly 210 according to a further embodiment of the invention. The microelectronic assembly 210 includes a package substrate subassembly 212, a die subassembly 214, two redistribution conductors formed by elongate redistribution pads 270, and redistribution wirebonding wires 272.

The package substrate subassembly 212 includes a substrate 218, solder ball contacts 224 on a lower side of the substrate 218, and terminals 222 on an upper surface of the substrate 218.

The die subassembly 214 includes a die 225 and plurality of contacts 226 on the die 224. The die 225 includes a die substrate and an integrated circuit formed on the die substrate.

The terminal 222A is connected through the redistribution wirebonding wire 272A to the contact 226A. The contact 226A is connected through the redistribution wirebonding wire 272B to the redistribution pad 270A. The redistribution pad 270A is connected through the wirebonding wire 272C to the contact 226B. The contact 226B is connected to the integrated circuit of the die subassembly 214. Similarly, a redistribution conductor is formed by the redistribution terminal 222B, redistribution wirebonding wire 272D, redistribution contact 226C, redistribution wirebonding wire 272E, redistribution pad 270B, redistribution wirebonding wire 272F, and contact 226D.

It can thus be seen that two redistribution conductors are formed, each with a respective redistribution pad 272. The redistribution pads 272 allow for more flexibility in design of redistribution conductors.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A microelectronic assembly, comprising:
at least a first die, having an integrated circuit formed therein;
at least one redistribution conductor, including a pair of contacts on the die; and
at least one pair of redistribution wirebonding wires, each redistribution wirebonding wire having a respective die portion, the die portions of the respective wirebonding wires being attached to the respective contacts of the redistribution conductor.

2. The microelectronic assembly of claim 1, further comprising:
a plurality of redistribution conductors, each including a respective pair of contacts on the die; and
a plurality of pairs of redistribution wirebonding wires, each redistribution wirebonding wire having a respective die portion, the die portions of the respective wirebonding wires being attached to the respective contacts of the redistribution conductors so as to connect a respective one of the pairs of redistribution wirebonding wires through a respective redistribution conductor to one another.

3. The microelectronic assembly of claim 1, wherein the redistribution conductor includes a wirebonding wire between the contacts.

4. The microelectronic assembly of claim 1, further comprising:
at least a first component other than the die;
at least a first terminal on the first component, a first of the redistribution wires of the pair having a component portion attached to the terminal.

5. The microelectronic assembly of claim 4, further comprising:
at least a second terminal on the first component, the other redistribution wire of the pair having a component portion attached to the terminal.

6. The microelectronic assembly of claim 4, wherein the component is a substrate to which the die is mounted and the terminal is outside an area of the die.

7. The microelectronic assembly of claim 4, wherein the component is a second die, having an integrated circuit formed therein, mounted on the first die, the terminal being located within an area of the first die on the second die.

8. The microelectronic assembly of claim 4, further comprising:
at least a third contact on the die, a second of the redistribution wirebonding wires of the pair having apportion attached to the third contact.

9. A microelectronic assembly, comprising:
a substrate;
a microelectronic die having an integrated circuit formed therein, mounted to the substrate;
a pair of redistribution terminals on the substrate; and
a redistribution conductor interconnecting the redistribution terminals, the redistribution conductor including a redistribution contact on the die and a wirebonding wire having first and second portions attached to one of the redistribution terminals and to the redistribution contact, respectively.

10. The microelectronic assembly of claim 9, further comprising:
a plurality of pairs of redistribution terminals on the substrate; and
a plurality of redistribution conductors, each interconnecting the redistribution terminals of a respective pair, each redistribution conductor including a redistribution contact on the die and a wirebonding wire having first and second portions attached to one of the redistribution terminals and to one of the redistribution contacts, respectively.

11. The microelectronic assembly of claim 9, wherein the redistribution conductor includes a pair of redistribution contacts on the die and a pair of redistribution wirebonding wires, each redistribution wirebonding wire having a respective first portion attached to a respective one of the redistribution terminals of the pair and a respective redistribution contact of the pair.

12. A microelectronic assembly, comprising:
a substrate;
a microelectronic die, having an integrated circuit formed therein, mounted to the substrate;
a plurality of functional terminals on the substrate;
a plurality of functional contacts on the die, each being connected to the integrated circuit;
a plurality of functional wirebonding wires, each having a first portion attached to a respective functional terminal and a second portion attached to a respective functional contact;
a pair of redistribution terminals on the substrate; and
a redistribution conductor interconnecting the redistribution terminals, the redistribution conductor including a redistribution contact on the die and a wirebonding wire having first and second portions attached to one of the redistribution terminals and to the resdistribution contact, respectively.

13. The microelectronic assembly of claim 12, wherein the redistribution conductor is not connected to the integrated circuit between the redistribution contacts.

14. The microelectronic assembly of claim 12, wherein the redistribution conductor includes a pair of redistribution contacts on the die and a pair of redistribution wirebonding wires, each redistribution wirebonding wire having a respective first portion attached to a respective one of the redistribution terminals of the pair and a respective redistribution contact of the pair.

15. A microelectronic assembly, comprising:
a first die, having an integrated circuit formed therein;
a redistribution conductor, including a pair of contacts on the first die and a portion interconnecting the contacts;
a second die, having an integrated circuit formed therein, mounted at least partially over the portion on the first die;
a terminal on the second die; and
a first redistribution wirebonding wire, having a first portion attached to the terminal and a second portion attached to a first redistribution contacts of the pair.

16. The microelectronic assembly of claim 15, further comprising:
a second redistribution wirebonding wire, having a portion attached to a second redistribution contact of the pair.

17. The microelectronic assembly of claim 15, wherein the terminal is connected to the integrated circuit of the second die.

18. The microelectronic assembly of claim 15, further comprising:
a substrate, the second die being mounted via the first die to the substrate;
a terminal on the substrate; and
a second redistribution wire, having a first portion attached to the second redistribution contact of the pair and a second portion attached to the terminal on the substrate.
